(19) United States
(12) Patent Application Publication
(10) Pub. No.: US 2026/0182341 A1
(43) Pub. Date: Jun. 25, 2026

(54) NON-VOLATILE MEMORY DEVICE AND PRODUCTION METHOD

(71) Applicant: COMMISSARIAT A L'ENERGIE ATOMIQUE ET AUX ENERGIES ALTERNATIVES, Paris (FR)

(72) Inventors: Thibaut CHENE, Grenoble cedex 09 (FR); Fabrice NEMOUCHI, Grenoble cedex 09 (FR); Roselyne SEGAUD, Grenoble cedex 09 (FR); Christelle BOIXADERAS, Grenoble cedex 09 (FR); Thierry CHEVOLLEAU, Grenoble cedex 09 (FR); Laurent GRENOUILLET, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/425,824

(22) Filed: Dec. 18, 2025

(30) Foreign Application Priority Data
Dec. 20, 2024 (FR) FR2414893

(51) Int. Cl. H10W 20/42; H10B 53/20; H10D 30/01; H10D 30/69; H10D 64/01; H10D 64/68; H10W 20/41

(52) U.S. Cl. CPC H10W 20/422; H10B 53/20; H10D 30/0415; H10D 30/701; H10D 64/033; H10D 64/689; H10W 20/435

(57) ABSTRACT

A memory device comprising: a transistor, an interconnection connecting the source, including a line, a via, a first portion of an etching stop layer inserted between the via and the line, a memory element connecting the drain, including a first electrode comprising a line, a via, and a second portion of the stop layer inserted between the two, a layer with the basis of a dielectric or ferroelectric material covering the line and the via, and a second electrode surmounting the layer, and an interconnection connecting the gate, including a line, a via, and a third portion of the stop layer inserted between the two.

### TECHNICAL FIELD

The present invention relates to the technical field of memory devices for microelectronics. It has a particularly advantageous application in the formation of non-volatile memory devices integrated in back end of line levels of microelectronic chip.

### PRIOR ART

Non-volatile memories, for example, OxRAM (Oxide-Based Random Access Memory)-type oxide-based resistive memories, or FeRAM (Ferroelectric Random Access Memory)-type ferroelectric memories, are currently developed with the aim of replacing Flash-type memories. These memory devices have, in particular, the advantage of being integrable with the back end of line (BEOL) method of CMOS (Complementary Metal-Oxide-Semiconductor) technology.

Memory devices typically comprise a multitude of memory cells arranged in the form of a matrix. For a resistive memory, each memory cell typically comprises a resistive memory element (“1R”) associated with a selection transistor (“1T”), according to a so-called “1T1R” configuration. The resistive memory element can reversibly switch between two resistive states, LRS (Low Resistive State) and HRS (High Resistive State), which correspond to logic values “0” and “1” used to code an information bit. Before obtaining these two LRS and HRS resistive states, it is generally necessary to apply a so-called “forming” voltage to condition the oxide layer of the resistive memory element. This forming voltage is significantly greater than the operating voltages associated with the LRS and HRS states. A challenge for this type of OxRAM memory is to minimise this forming voltage.

The basic cell of an FeRAM memory comprises, in particular, a ferroelectric capacitor, in which the information is stored in the form of the bias state of the electric dipoles. There again, the HfO₂ ferroelectric capacitor is connected to the drain of a selection transistor. A challenge for this type of FeRAM memory is to reduce the size of the memory cells, while preserving an operating range of the ferroelectric capacitor accessible to the selection transistor.

An aim of the present invention is to respond to these challenges, by overcoming all or some of the disadvantages mentioned above.

In particular, an aim of the present invention is to propose a non-volatile memory device integrated in the back end of line levels of a microelectronic chip. Another aim of the present invention is to propose a method for forming such a device.

### SUMMARY

To achieve this aim, according to an embodiment, a non-volatile memory device is provided, comprising, in a stack along a direction z:
a selection element comprising at least two electrodes,
an interconnection connecting one of said at least two electrodes,
a memory element comprising:
   a first electrode connecting the other of said at least two electrodes of the selection element, the first electrode comprising:
      a metal line with the basis of a first metal and,
      a metal via with the basis of a second metal,
      a portion of an etching stop layer inserted between the via and the line, said portion comprising at least one via opening, such that the via and the line are connected through said at least one via opening,
   a layer with the basis of a dielectric or ferroelectric material covering the line and the via,
   a second electrode surmounting the layer with the basis of the dielectric or ferroelectric material.

Such a memory device advantageously has a memory element integrated in the “Back End” interconnecting levels, typically comprising metal lines and vias.

Advantageously, the layer with the basis of a dielectric or ferroelectric material covers the line and the via forming the first electrode of the memory element. It typically has a three-dimensional shape surrounding the first electrode. This makes it possible to increase the surface of the layer with the basis of a dielectric or ferroelectric material.

When this layer is with the basis of a dielectric material, an OxRAM-type memory device is typically formed. By increasing the surface of the layer with the basis of a dielectric material of an OxRAM memory device, the forming voltage is advantageously decreased.

When this layer is with the basis of a ferroelectric material, an FeRAM-type memory device is typically formed. By increasing the surface of the layer with the basis of a ferroelectric material of an FeRAM memory device, the operating range of the ferroelectric capacitor accessible to the selection transistor is extended. This makes it possible to compensate for reducing, by size, the FeRAM memory device. The integration of the FeRAM memory device is improved.

The invention also provides, according to a second aspect, a method for manufacturing such a non-volatile memory device. The method comprises:
a provision of a selection element comprising at least two electrodes, each having an exposed face at an upper surface,
a formation of a first metal layer on the exposed faces of the upper surface,
a formation, on the first metal layer, of an etching stop layer, said etching stop layer preferably having a selectivity at the etching S_{21:30} greater than or equal to 5:1 with respect to the first metal layer,
a structuration of the etching stop layer, through a first mask, so as to expose parts of the first metal layer and to preserve parts of the etching stop layer in the form of a portion surmounting one of said at least two electrodes of the selection element, said portion comprising a via opening, opening onto the first underlying metal layer,
a formation of a second metal layer on the portion of the etching stop layer and on the exposed parts of the first metal layer,
a formation, on the second metal layer, of a second mask defining at least one via in vertical alignment with the via opening of the portion of the etching stop layer, and at least partially, an interconnection in vertical alignment with the other of said at least two electrodes of the selection element,
an etching of the second metal layer, said etching being configured to form, by stopping on the portion of the etching stop layer, a via in vertical alignment with the via opening of said portion, and at least partially, the interconnection,
an etching of the first metal layer on either side of the portion of the etching stop layer, said etching being configured to form, by stopping on the upper surface, a metal line under said portion, the via and the metal line forming a first electrode of a memory element of the device, said etching preferably being configured to further form the interconnection,
a formation of a layer with the basis of a dielectric or ferroelectric material on the first electrode,
a formation of a third metal layer on the layer with the basis of a dielectric or ferroelectric material,
a formation, on the third metal layer, of a third mask defining at least one via in vertical alignment with the interconnection, and defining a second electrode of the memory element in vertical alignment with layer with the basis of a dielectric or ferroelectric material,
an etching of the third metal layer, said etching being configured to form or reform the interconnection, said etching being configured to form, by stopping on the upper surface or on the layer with the basis of a dielectric or ferroelectric material, the second electrode of the memory element.

The advantages described above facing the device are applied mutatis mutandis to the method according to the invention. According to an advantageous option, the etching of the second metal layer and the etching of the first metal layer are sequenced according to one single and same sequence of etchings. This makes it possible to limit the number of steps of the method.

### BRIEF DESCRIPTION OF THE FIGURES

The aims, objectives, as well as the features and advantages of the invention will best emerge from the detailed description of embodiments of the latter, which are illustrated by the following accompanying drawings, in which:

FIGS. 1A to 19A schematically illustrate, in a cross-section, in a plane xz, different steps of the method for manufacturing a 3D non-volatile memory device according to an embodiment of the present invention.

FIGS. 1B to 19B schematically illustrate, in perspective, the steps of the method for manufacturing the 3D non-volatile memory device, illustrated respectively in FIGS. 1A to 19A, according to an embodiment of the present invention.

The drawings are given as examples and are not limiting of the invention. They constitute principle schematic representations intended to facilitate the understanding of the invention, and are not necessarily to the scale of practical applications. In particular, the thicknesses and/or the dimensions of the different layers and patterns are not representative of reality. For reasons of clarity, all of the alphanumeric references are not systematically repeated from one figure to another. It is understood that the elements already described and referenced, when they are reproduced in another figure, typically have the same alphanumeric references, even if these are not explicitly mentioned. A person skilled in the art will identify, without difficulties, one same element reproduced in different figures.

### DETAILED DESCRIPTION

Before starting a detailed review of embodiments of the invention, optional features are stated below, which can optionally be used in association or alternatively.

According to an example, the layer with the basis of a dielectric or ferroelectric material has at least one so-called horizontal portion, extending perpendicularly to the direction z, separating the first and second electrodes, and at least one so-called vertical portion, extending parallel to the direction z, separating the first and second electrodes. The layer with the basis of a dielectric or ferroelectric material typically has a three-dimensional shape surrounding the first electrode, and surrounded by the second electrode. The layer surface interfaced between the first and second electrodes is increased.

According to an example, the at least one horizontal portion comprises a first horizontal portion on the metal via of the first electrode and a second horizontal portion on the portion of the etching stop layer of the memory element. The portion of the etching stop layer corresponds to a residual element linked to the implementation of the method according to the invention, making it possible to manufacture the device according to the invention. This residual element in the device can therefore be an implementation indicator of the method according to the invention.

According to an example, the at least one vertical portion comprises a first vertical portion on at least one flank of the metal via of the first electrode and a second vertical portion on at least one flank of the metal line of the first electrode.

According to an example, the metal via of the first electrode of the memory element has a critical dimension CDᵥᵢₐ₂₂₁, taken along an axis x perpendicular to the direction z, greater than or equal to a dimension CDₒₚₑₙ of the at least one via opening taken along the axis x. This makes it possible to introduce a certain tolerance in the alignment between the first and second masks. The via typically being wider than the underlying via opening, the alignment of the second mask defining the vias in vertical alignment with the via openings is facilitated. The etching of the second metal layer, during the formation of the vias, will actually stop on the etching stop layer, structured along the second portion. The etching of the second metal layer does not extend at the via openings. The risk linked to a misalignment between the first and second masks is minimised. The reliability of the method is increased.

According to an example, the metal via of the first electrode of the memory element has a critical dimension CDᵥᵢₐ₂₂₁, taken along an axis x, substantially equal to a dimension CDₗᵢₙₑ, taken along the axis x, of the metal line of the first electrode of the memory element, such that the second portion of the etching stop layer is sandwiched between the via and the line.

According to an example, the metal line(s) has/have a critical dimension CDₗᵢₙₑ, taken along an axis x, substantially equal to a dimension CD₁, taken along the axis x, of the portion(s) of the etching stop layer associated with said lines.

According to an example, the layer with the basis of a dielectric or ferroelectric material is with the basis of a material taken from among: doped or non-doped HfₓZr₁₋ₓO₂, HfO₂. HfO₂ is a metal oxide which can advantageously have dielectric and/or ferroelectric properties, according to its thickness, in particular, and its doping level.

According to an example, the layer with the basis of a dielectric or ferroelectric material is with the basis of a ferroelectric material taken from among: HfₓZr₁₋ₓO₂, HfO₂ doped by at least one from among the following doping elements: Si, N, Gd, Y, Sc, Ge, with a concentration of doping elements of between 0.5% and 10% at., preferably between 0.5% and 3% at.

According to an example, the layer with the basis of a dielectric or ferroelectric material is with the basis of a dielectric material taken from among: HfOₓ, TaOₓ with 1.8≤x≤2. HfOₓ can be, in this case, slightly doped (typically with a concentration of doping elements less than 0.5% at.) or non-doped.

According to an example, the etching stop layer has a thickness e₃₀ₐ Of between 2 nm and 15 nm, preferably between 7 nm and 10 nm.

According to an example, the selection element is taken from among: a field effect transistor or a field effect ferroelectric transistor, a diode, a selector.

According to an example, the layer with the basis of a dielectric or ferroelectric material has a thickness e_{30b} of between 2 nm and 15 nm, preferably between 7 nm and 10 nm.

According to an example, the non-volatile memory device comprises, in a stack along a direction z:
a transistor comprising a gate surmounting a channel, a source and a drain on either side of the channel,
an interconnection connecting the source, comprising:
   a metal line with the basis of a first metal, connected to the source and,
   a metal via with the basis of a second metal, connected to said at least one metal line,
   a first portion of an etching stop layer inserted between the via and the line, said etching stop layer having a selectivity at the etching S21:30 greater than or equal to 5:1 with respect to the first metal, said first portion comprising at least one via opening, such that the via and the line are connected through said at least one via opening,
a memory element connecting the drain, comprising:
   a first electrode connected to the drain comprising:
      a metal line with the basis of the first metal and,
      a metal via with the basis of the second metal,
      a second portion of the etching stop layer inserted between the via and the line, said second portion comprising at least one via opening, such that the via and the line are connected through said at least one via opening,
   a layer with the basis of a dielectric or ferroelectric material covering the line and the via,
   a second electrode surmounting the layer with the basis of the dielectric or ferroelectric material,
an interconnection connecting the gate, comprising:
   a metal line with the basis of the first metal, connected to the gate and,
   a metal via with the basis of the second metal,
   a third portion of the etching stop layer inserted between the via and the line, said third portion comprising at least one via opening, such that the via and the line are connected through said at least one via opening.

According to an example, the etching of the second metal layer and the etching of the first metal layer are sequenced along one and same sequence of etchings. This sequence of etchings can comprise several substeps with different plasma conditions, for example.

According to an example, the etching of the second metal layer and the etching of the first metal layer are done by one single and same etching, during one single and same step. The etching conditions remain substantially identical during the etching of the second and first metal layers. This makes it possible to reduce the duration and/or the costs of the method.

According to an example, the formation of the layer with the basis of the dielectric or ferroelectric material comprises:
a conform deposition of the layer with the basis of the dielectric or ferroelectric material on the first electrode and on the interconnection, then
a structuration by lithography and etching, so as to remove parts of the layer with the basis of the dielectric or ferroelectric material deposited on the interconnection, and to preserve a part of the layer with the basis of the dielectric or ferroelectric material deposited on the first electrode.

According to an alternative example, the formation of the layer with the basis of the dielectric or ferroelectric material comprises:
a formation of a protective layer on the interconnection, then
a localised deposition of the layer with the basis of the dielectric or ferroelectric material on the first electrode,
a removal of said protective layer.

According to an example, the method further comprises, after formation of the layer with the basis of the dielectric or ferroelectric material, a deposition of a diffusion barrier layer, for example, titanium-based.

According to an example, the formation of the first mask is done by double lithography. This known lithography method makes it possible to optimise, even exceed the limitations in resolution of a conventional piece of lithography insolation equipment. Another solution consists of using better resolved lithography equipment, for example, in extreme UV or in electronic lithography. The formation of the first mask can comprise a first lithography followed by a second lithography, then an etching. Alternatively, the formation of the first mask can comprise a first lithography followed by a first etching, then a second lithography followed by a second etching.

According to an example, the first metal and/or the second metal are with the basis of at least one from among: TIN, TaN, W, Ru, Ta, Al.

According to an example, the first and second metals are with the basis of the same material.

According to an example, the etching stop layer is with the basis of a material taken from among: SiO₂, TiO₂, HfO₂, HfN, ZrN, SiN, SiCN. This makes it possible to obtain a selectivity S_{21:30} at the etching between the first metal and the material of the etching stop layer greater than or equal to 5:1. The etching speed of the etching stop layer is at least five times less than the etching speed of the first metal layer. According to an example, the selectivity S_{21:30} is greater than 10:1.

According to an example, the method comprises:
a provision of a transistor comprising a gate surmounting a channel, a source and a drain on either side of the channel, and vias connecting the source and the drain, said vias and said gate each having an exposed face at an upper surface,
a formation of a first metal layer on the exposed faces of the upper surface,
a formation, on the first metal layer, of an etching stop layer having a selectivity at the etching S_{21:30} greater than or equal to 5:1 with respect to the first metal layer,
a structuration of the etching stop layer, through a first mask, so as to expose parts of the first metal layer and to preserve parts of the etching stop layer in the form of first and second portions, each surmounting vias connecting the source and the drain, and of a third portion surmounting the gate of the transistor, said first, second and third portions, each comprising a via opening, opening onto the first underlying metal layer,
a formation of a second metal layer on the first, second and third portions of the etching stop layer and on the exposed parts of the first metal layer,
a formation, on the second metal layer, of a second mask defining vias in vertical alignment with the via openings of the first, second and third portions of the etching stop layer,
an etching of the second metal layer, said etching being configured to form, by stopping on the first, second and third portions of the etching stop layer, respectively a first via in vertical alignment with the via opening of the first portion, a second via in vertical alignment with via opening of the second portion, a third via in vertical alignment with the via opening of the third portion,
an etching of the first metal layer on either side of the first, second and third portions of the etching stop layer, said etching being configured to form, by stopping on the upper surface, a first metal line under the first portion, a second metal line under the second portion, a third metal line under the third portion, the second via and the second metal line forming a first electrode of a memory element of the device,
a formation of a layer with the basis of a dielectric or ferroelectric material on the first electrode,
a formation of a third metal layer on the layer with the basis of a dielectric or ferroelectric material and on the second and third vias,
a formation, on the third metal layer, of a third mask defining vias in vertical alignment with the via openings of the first and third portions of the etching stop layer, and defining a second electrode of the memory element in vertical alignment with the layer with the basis of a dielectric or ferroelectric material,
an etching of the third metal layer, said etching being configured to form or reform, by stopping on the first and third portions of the etching stop layer, respectively the first via in vertical alignment with the via opening of the first portion, the third via in vertical alignment with the via opening of the third portion, said etching being configured to form, by stopping on the upper surface or on the layer with the basis of a dielectric or ferroelectric material, the second electrode of the memory element.

Unless incompatible, it is understood that all of the optional features above and/or the indicated variants can be combined, so as to form an embodiment, which is not necessarily illustrated or described. Such an embodiment is clearly not excluded from the invention.

It is specified that, in the scope of the present invention, the terms “on”, “surmounts”, “covers”, “opposite” and their equivalents do not necessarily mean “in contact with”. Thus, for example, the deposition or the application of a first layer on a second layer, does not compulsorily mean that the two layers are directly in contact with one another, but means that the first layer at least partially covers the second layer, by being either directly in contact with it, or by being separated from it by at least one other layer or at least one other element.

By a substrate, a film, a layer, “with the basis” of a material A, this means a substrate, a film, a layer comprising this material A only or this material A, and optionally other materials, for example, doping elements or alloy elements. Thus, a silicon nitride SiN-based spacer can, for example, comprise non-stoichiometric silicon nitride (SiN), or stoichiometric silicon nitride (Si₃N₄), or also a silicon oxynitride (SiON) or a silicon carbonitride (SiCN).

The word “dielectric” qualifies a material, the electric conductivity of which is sufficiently low in the given application to serve as an insulator. In the present invention, a dielectric material preferably has a dielectric constant less than 20, and preferably less than 10.

The dielectric layer of an OxRAM resistive memory is, for example, an HfO₂-based metal oxide layer disposed between the two electrodes of the memory element. Contrary to the present invention, a known solution making it possible to decrease the forming voltage of such an OxRAM memory consists of implanting silicon in the HfO₂-based metal oxide layer, as disclosed in the document, “16 kbit 1T1R OxRAM arrays embedded in 28 nm FDSOI technology demonstrating low BER, high endurance, and compatibility with core logic transistors, L. Grenouillet et al, IMW 2021”.

When the HfO₂ material is deposited in thin layers, this advantageously has ferroelectric properties. It is therefore also possible to consider the manufacture of an FeRAM-type memory device according to the principle of the present invention.

The present invention more generally addresses the manufacture of all types of three-dimensional, or 3D non-volatile memories.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of the phases of the method. The etchings of the first and second metal layers can, in particular, be sequenced or be considered as forming part of one single and same etching step.

By “selective etching with respect to” or “etching having a selectivity with respect to” means an etching configured to remove a material A or a layer A with respect to a material B or a layer B, and having an etching speed of the material A, greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a metal layer typically has a thickness along z. A via formed from such a metal layer has a height along z. The relative terms “on”, “surmounts”, “upper”, “under”, “underlying”, “lower” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element means that these two elements are both located on one same line perpendicular to a plane into which a lower or upper face of a substrate mainly extends, i.e. on one same line oriented vertically in the figures, in a cross-section.

The terms “substantially”, “around”, “about” mean plus or minus 10%, and preferably plus or minus 5%. Moreover, the terms “between . . . and . . . ” and equivalents mean that the limits are inclusive, unless mentioned otherwise.

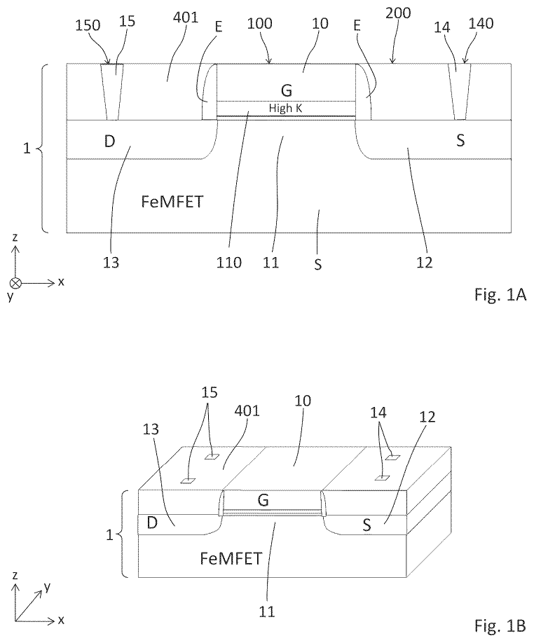

Steps of manufacturing a 3D non-volatile memory device according to an embodiment of the invention are illustrated in FIGS. 1A, 1B to 19A, 19B.

As illustrated in FIGS. 1A, 1B, the method comprises a provision of a transistor 1, for example, of the MOS (metal-oxide-semiconductor) type. This transistor 1 typically comprises a silicon-based substrate S, a gate 10 surmounting the substrate S, a source 12 and a drain 13 on either side of the gate 10, for example, within the substrate S, and a channel 11 under the gate 10 and separated from the gate 10 by one or more dielectric layers 110. The gate 10 is typically flanked by spacers E.

The transistor 1 also comprises, in this case, the vias 14, 15 respectively connecting the source 12 and the drain 13 of the transistor. These vias 14, 15 are preferably obtained according to a “damascene” approach. According to this approach, after formation of the gate 10 and of the source 12 and drain 13 of the transistor, a dielectric layer 401 is deposited. This dielectric layer 401 is typically planarised by chemical-mechanical polishing CMP, so as to expose an upper face 100 of the gate 10. Openings, opening onto the source 12 and drain 13 of the transistor are formed within the dielectric layer 401, then filled by a metal. A planarisation, for example, by CMP, is done, so as to remove the metal on the surface of the dielectric layer 401 and from the upper face of the gate 10. The vias 14, 15 are thus obtained. They respectively have exposed faces 140, 150, coplanar with the upper face 100 of the gate 10. The upper surface 200 of this transistor 1, comprising the exposed faces 140, 150, 100, is advantageously flat.

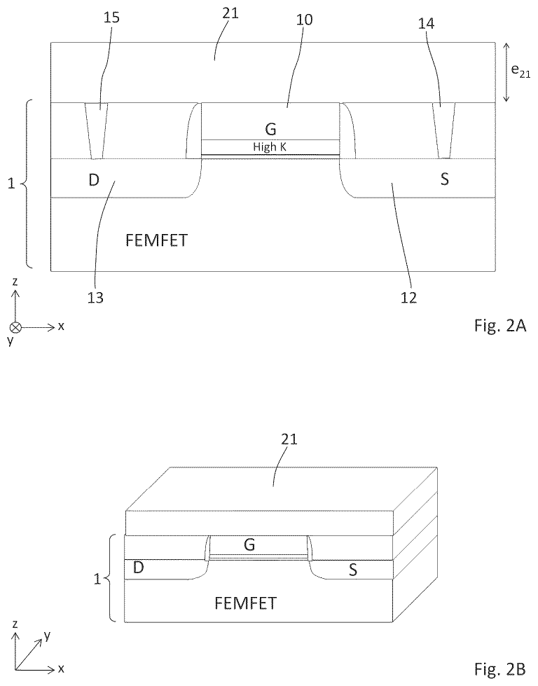

As illustrated in FIGS. 2A, 2B, a first metal layer 21, typically with the basis of a metal taken from among TaN, TiN, Al, Ru, Mo, W is first formed on the surface 200 of the transistor 1. The vias 14, 15 and the gate 10 are directly in contact with the metal layer 21. This metal layer 21 typically has a thickness e₂₁ of around a few tens of nanometres to a few hundreds of nanometres, for example, between 20 nm and 200 nm. The deposition of this metal layer 21 can, in particular, be done by one of the following techniques: physical vapour deposition (PVD), chemical vapour deposition (CVD), atomic layer deposition (ALD). After deposition, the first metal layer 21 can be planarised, for example, by CMP. The first metal layer 21 typically corresponds to a first metal level.

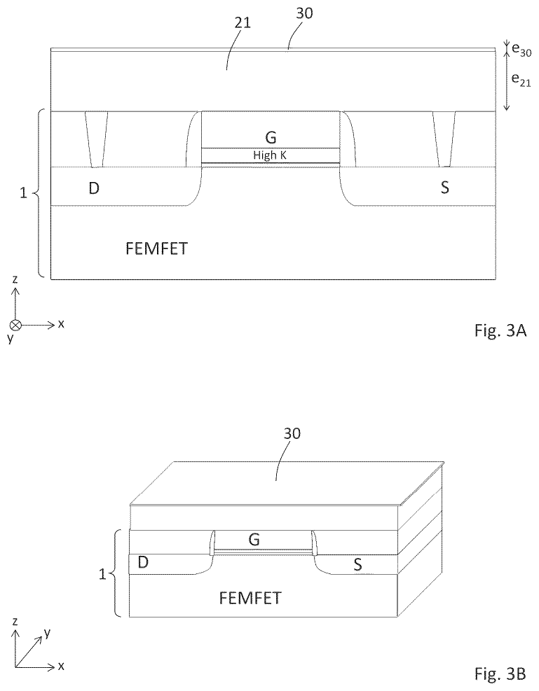

As illustrated in FIGS. 3A, 3B, an etching stop layer 30 is then directly formed on the first metal layer 21. This etching stop layer 30 typically has a thickness e₃₀ of around a few nanometres, for example, between 2 nm and 15 nm. It is preferably with the basis of a dielectric material, taken from among: SiO₂, TiO₂, HfO₂, HfN, ZrN, SiN, SiCN. The deposition of this etching stop layer 30 is preferably done by ALD.

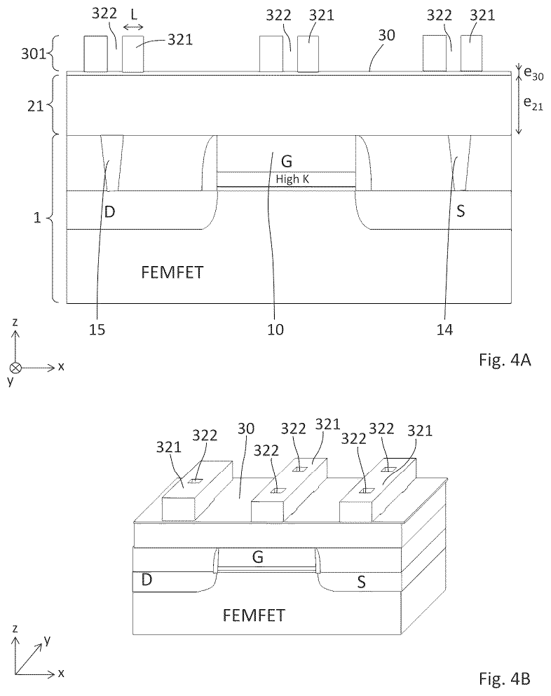

As illustrated in FIGS. 4A, 4B, an etching mask 301 is formed on the etching stop layer 30. This etching mask 301 is, for example, SiON-based. It is typically obtained by lithography/etching, for example, through an extreme UV insolation simple lithography, or through a double lithography, also called “double patterning”.

The etching mask 301 comprises open patterns 321 above the vias 14, 15 and the gate 10 of the transistor 1. The open patterns 321 comprise one or more openings 322, opening onto the underlying etching stop layer 30. The open patterns 321 typically have a dimension L along x of between 8 nm and 150 nm, according to the lithography technique implemented.

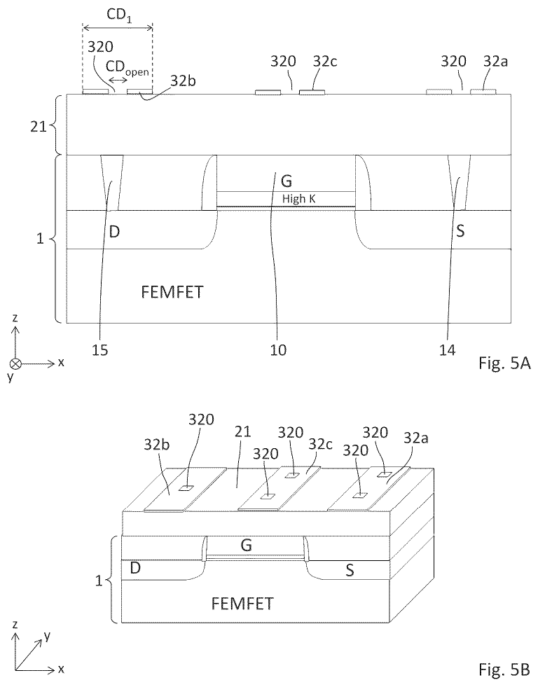

As illustrated in FIGS. 5A, 5B, the patterns 321 are transferred into the etching stop layer 30 by anisotropic etching along z of the etching stop layer 30 in the presence of the mask 301. This etching can have a chlorine-or fluorine-based halogenated etching chemistry, according to the type of mask 301 and the nature of the etching stop layer 30. For a hafnium-based etching stop layer 30, the etching can be done from an etching chemistry BCl₃. For a silicon-based etching stop layer 30, the etching can be done from a fluorocarbon etching chemistry, for example, CF₄. After etching, the portions 32a, 32b, 32c comprising the via openings 320 are formed from the etching stop layer 30. The portions 32a, 32b, 32c have substantially the same dimensions as the patterns 321. The portions 32a, 32b, 32c typically have a dimension CD₁ along x, and the via openings 320 typically have a dimension CDₒₚₑₙ along x. The portions 32a, 32b, 32c can each have the same dimensions CD₁, CDₒₚₑₙ. Alternatively, the portions 32a, 32b, 32c can respectively have the dimensions CD₁ₐ, CD_{open_a}, CD_{1b}, CD_{open_b}, CD_{1c}, CD_{open_c} different from one another. The mask 301 is removed after etching, for example, by oxygen-based plasma.

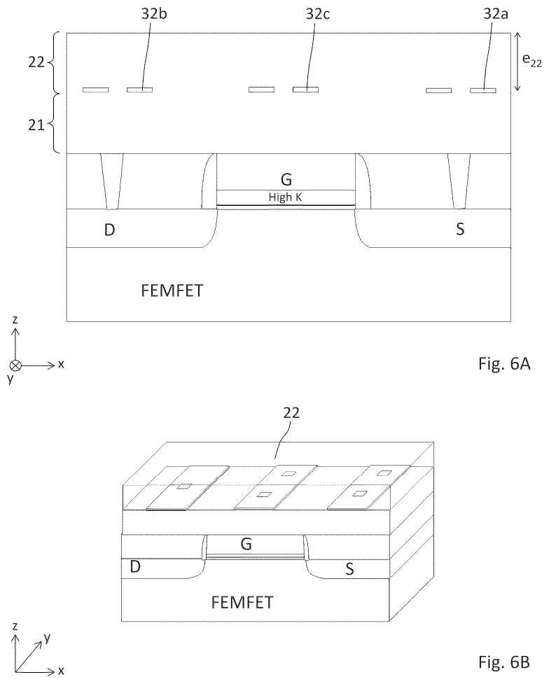

As illustrated in FIGS. 6A, 6B, after structuration of the etching stop layer 30, a second metal layer 22, typically with the basis of a metal taken from among TaN, TiN, Al, Ru, Mo, W, is then formed on the first metal layer 21, and on the portions 32a, 32b, 32c. This metal layer 22 typically has a thickness e₂₂ of around a few tens of nanometres to a few hundreds of nanometres, for example, between 20 nm and 200 nm. The deposition of this metal layer 22 can, in particular, be done by PVD, CVD or ALD. After deposition, the second metal layer 22 can be planarised, for example, by CMP. The second metal layer 22 typically corresponds to a second metal level.

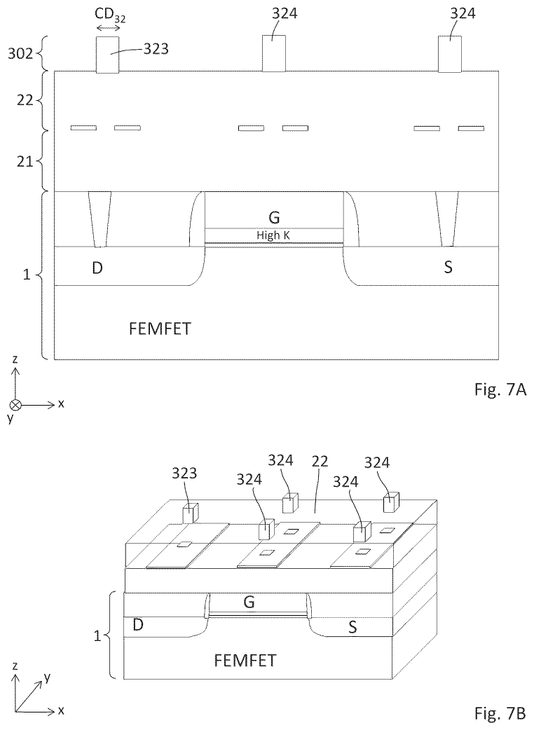

As illustrated in FIGS. 7A, 7B, a second etching mask 302 comprising via patterns 323, 324 is formed on the second metal layer 22. This second etching mask 302 is preferably organic layer-based, for example, in the form of a stack known as a “trilayer”, typically comprising an organic planarisation layer, an antireflective layer and a photosensitive resin layer.

The via patterns 324 of this second etching mask 302 are aligned in vertical alignment with the via openings 320 of the portions 32a, 32c. The via pattern 323 of this second etching mask 302 is aligned in vertical alignment with the portion 32b. The via patterns 323, 324 typically have a dimension CD₃₂ along x, slightly greater, for example 10% greater, than the dimension CDₒₚₑₙ along x of the via openings 320 of the portions 32a, 32b, 32c. This facilitates the alignment of the patterns 324, 323 and of the portions 32a, 32b, 32c to one another. A certain tolerance on the alignment accuracy is thus obtained. The dimension CD₃₂ along x of the via patterns 323, 324 is, for example, between 10 nm and 150 nm. According to an option, the pattern 323 has a dimension CD₃₂ along x greater than the dimensions CD₃₂ of the patterns 324. More generally, the dimensions along x and y of the pattern 323 can differ from the dimensions along x and y of the patterns 324.

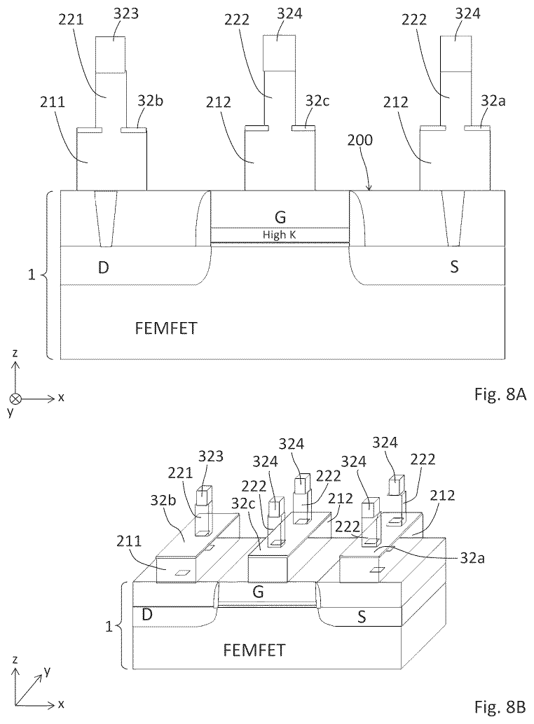

As illustrated in FIGS. 8A, 8B, the first and second metal layers 21, 22 are then etched over their entire thickness, along z, on either side of the via patterns 323, 324 and on either side of the portions 32a, 32b, 32c. The second metal layer 22 is first etched to form the vias 222, 221, then the first metal layer 21 is etched to form the lines 212, 211. The etchings of the first and second metal layers 21, 22 are preferably sequenced. According to an option, in particular when the first and second metal layers 21, 22 are of an identical nature, the etchings of these metal layers 21, 22 are done in one single and same step, with the same etching chemistry.

In this case, the etchings are chosen so as to selectively etch the first and second metals of the first and second metal layers 21, 22 with respect to the material of the etching stop layer 30 (structured in the form of the portions 32a, 32b, 32c). In particular, the etching selectivity S_{21:30}, i.e. the ratio between the etching speed of the metal of the first metal layer 21 on the etching speed of the material of the etching stop layer, is greater than or equal to 5:1, preferably greater than or equal to 10:1. The etchings can be with the basis of a halogenated chemistry, for example, fluorinated, if the first and second metal layers 21, 22 are Mo- or W-based, or chlorinated, if the first and second metal layers 21, 22 are TiN-based.

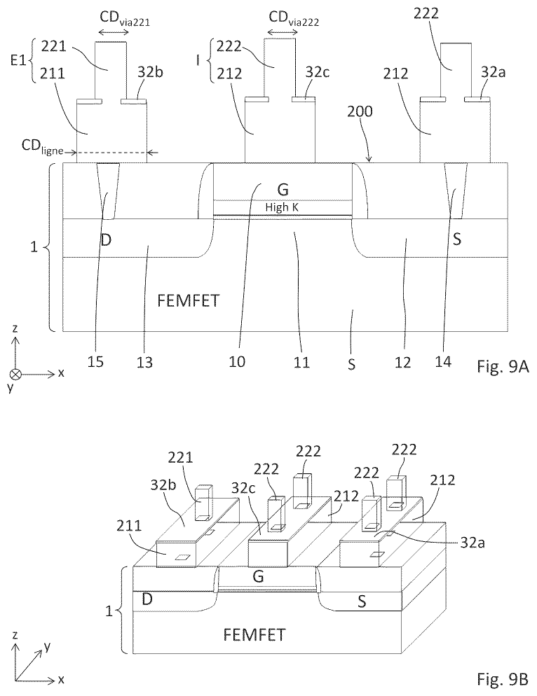

As illustrated in FIGS. 9A, 9B, after etching, the mask 302 is removed, for example, by oxygen-based plasma. Vias 222 having the dimension CDᵥᵢₐ₂₂₂ along x are obtained above the portions 32a, 32c. The dimension CDᵥᵢₐ₂₂₂ is substantially equal to the dimension CD₃₂ of the via patterns 324. A via 221 having the dimension CDᵥᵢₐ₂₂₁ along x is obtained above the portion 32b. The vias 222, 221 are located, in this case, in the second metal level. Lines 211, 212 having the dimension CDₗᵢₙₑ along x are also obtained. The dimension CDₗᵢₙₑ is substantially equal to the dimension CD₁ of the portions 32a, 32b, 32c. The lines 211, 212 are located, in this case, in the first metal level. A first electrode E1 (211, 221) connected to the drain 13 of the transistor is thus formed. Interconnections I (212, 222) connected respectively to the source 12 and to the gate 10 of the transistor are thus formed.

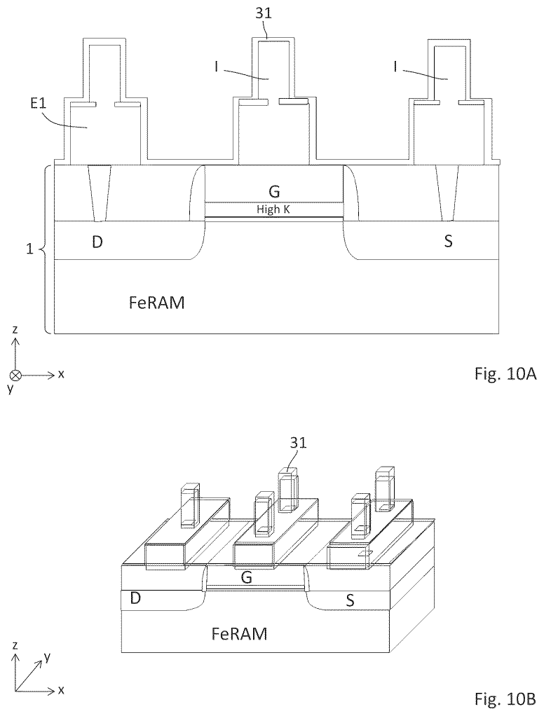

As illustrated in FIGS. 10A, 10B, a layer 31 with the basis of a dielectric or ferroelectric material is then formed on the first electrode E1 and on the interconnections I. This layer 31 can be with the basis of a dielectric material, for example, HfO₂, TaOₓ, or with the basis of a ferroelectric material, for example, doped HfₓZr₁₋ₓO₂, HfO₂. HfO₂ can typically be doped by at least one from among the following doping elements: Si, N, Gd, Y, Sc, Ge, with a concentration of doping elements of between 0.5% and 3% at., preferably. The layer 31 has a thickness of around a few nanometres, for example, of between 2 nm and 15 nm. The layer 31 is preferably deposited by ALD. The layer 31 with the basis of a dielectric or ferroelectric material is intended to form the separation layer between the electrodes of a memory element, for an OxRAM- or FeRAM-type memory. It is therefore preserved only on the first electrode E1 in the final device.

According to an option not illustrated, after formation of the layer 31, in particular when this is hafnium oxide-based, a deposition of a diffusion barrier layer, for example, titanium-based, can be done.

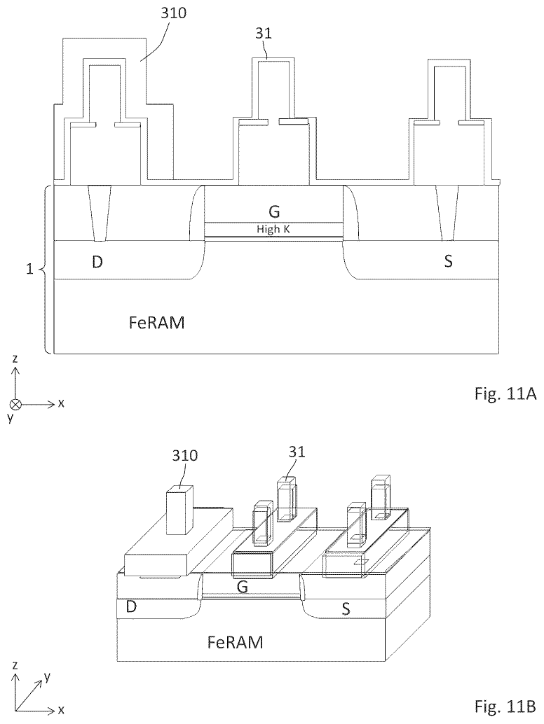

As illustrated in FIGS. 11A, 11B, a protective layer 310 is formed, typically by lithography, on a part of the layer 31 covering the first electrode E1. The parts of the layer 31 covering the interconnections I remain exposed.

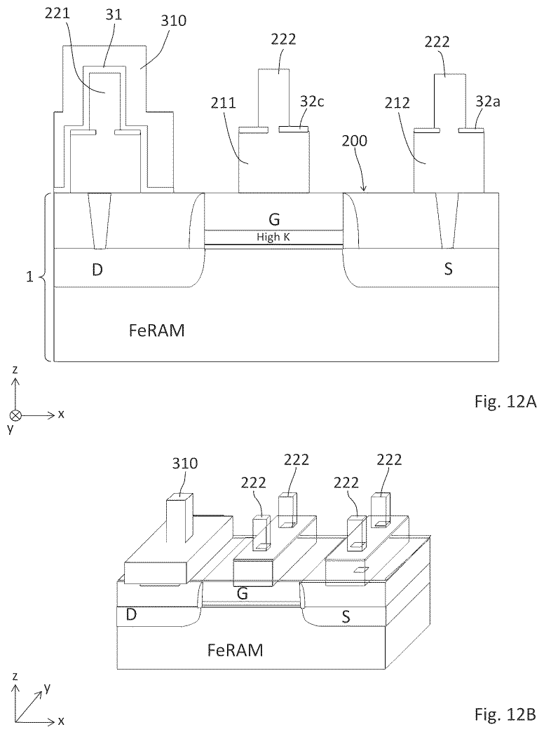

As illustrated in FIGS. 12A, 12B, the exposed parts of the layer 31 are removed, typically by etching. The interconnections I are exposed again. The layer 31 is, in this case, structured by lithography/etching. Other structuration techniques can be considered.

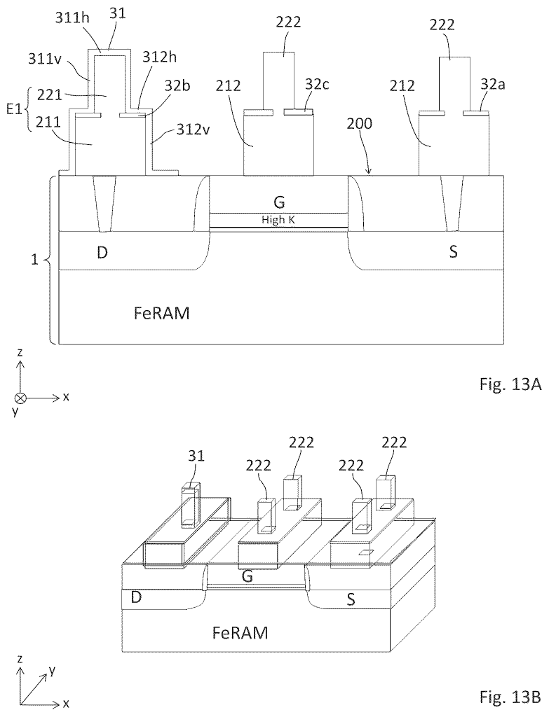

As illustrated in FIGS. 13A, 13B, after removal of the protective layer 310, a layer part 31 only covering the first electrode E1 is obtained. This layer part 31 has a three-dimensional shape. As the dimension CDₗᵢₙₑ of the line 211 is typically greater than the dimension CDᵥᵢₐ₂₂₁ of the via 221, the remaining layer 31 has a shoulder between the line 211 and the via 221. This shoulder typically bears on the etching stop layer portion 32b. The remaining layer 31 typically comprises a first horizontal portion 311h at the apex of the via 221 and a second horizontal portion 312h on the second portion 32b of the etching stop layer. The remaining layer 31 typically also comprises a first vertical portion 311v on the flank(s) of the via 221 and a second vertical portion 312v on the flank(s) of the line 211. The developed surface of the interface between the three-dimensional layer 31 and the first electrode E1 is significantly increased compared with a memory element architecture based on a 2D dielectric or ferroelectric layer inserted between the electrodes (the comparison being made for an equivalent memory element imprint on the microelectronic chip).

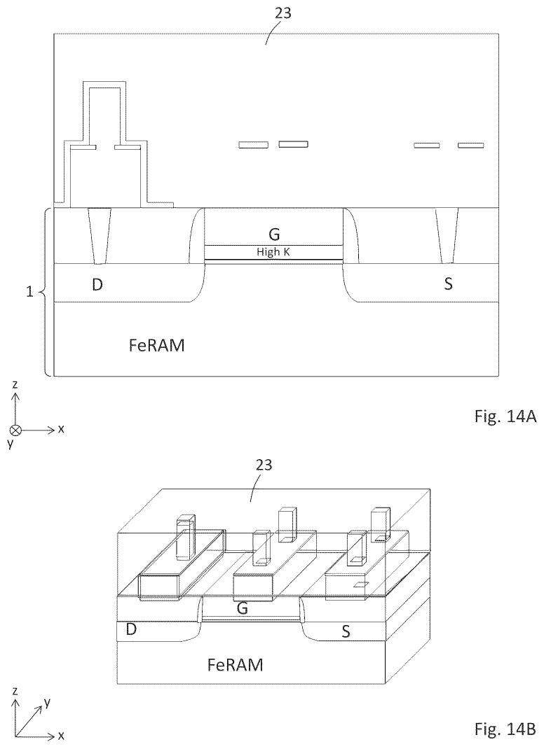

As illustrated in FIGS. 14A, 14B, a third metal layer 23, for example, TaN-, TiN-, Al-, Ru-, Mo-based, is then deposited on the layer 31 covering the first electrode E1 and on the interconnections I connected to the source and to the gate of the transistor. The deposition can be done by PVD, CVD or ALD, for example. The layer 23 thickness deposited can be between 30 nm and 600 nm, so as to entirely fill the spaces between the interconnections I. A CMP is typically done after deposition, in order to obtain a flat layer 23 upper surface. The upper surface of the layer 23 is located above the apex of the three-dimensional layer 31. The upper surface of the layer 23 is preferably separated from the apex of the three-dimensional layer 31 by at least a few tens of nanometres, for example, at least 20 nm. The metal layer 23 can correspond to a third metal level.

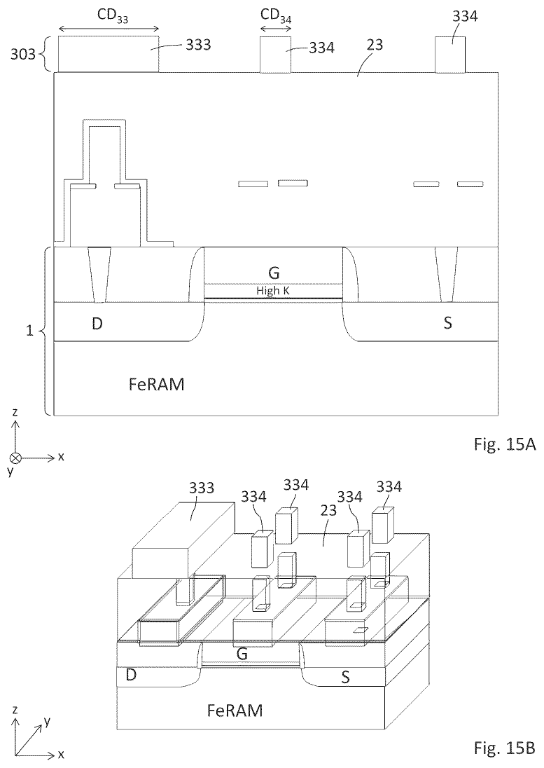

As illustrated in FIGS. 15A, 15B, a third mask 303 comprising, for example, via patterns 334 and an electrode pattern 333 is formed on the third metal layer 23. The via patterns 334 are aligned in vertical alignment with the vias 222. They preferably have a dimension CD34 less than the dimension CD₁ of the portions 32a, 32c. The electrode pattern 333 is aligned in vertical alignment with the remaining layer 31. It typically has a dimension CD₃₃ greater than the dimension CD₁ of the portion 32b.

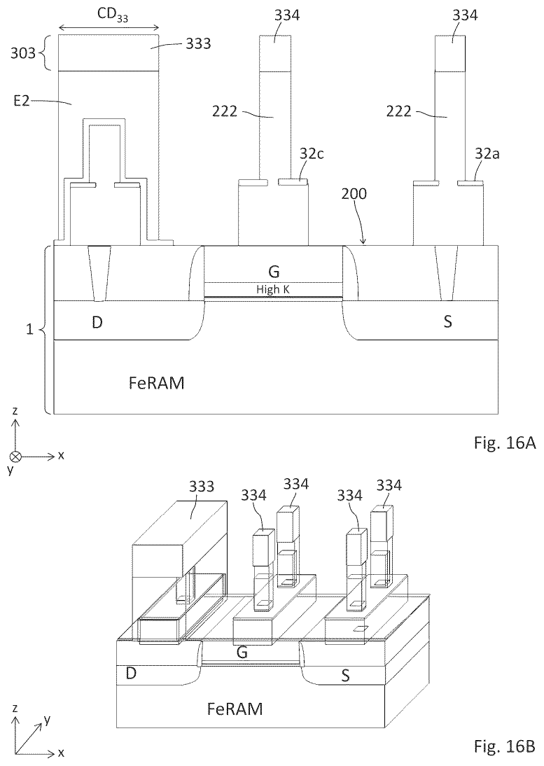

As illustrated in FIGS. 16A, 16B, the third metal layer 23 is then structured by etching through the mask 303. The etching is done up to the surface 200, along the first, second and third metal levels. A second electrode E2 surmounting the three-dimensional layer 31 is thus formed. The developed surface of the interface between the three-dimensional layer 31 and the second electrode E2 is significantly increased compared with a memory element architecture based on a 2D dielectric or ferroelectric layer inserted between the electrodes (the comparison being made for an equivalent memory element imprint on the microelectronic chip). The vias 222 and the lines 212 are also reformed during this etching. The vias 222 now extend along the second and third metal levels.

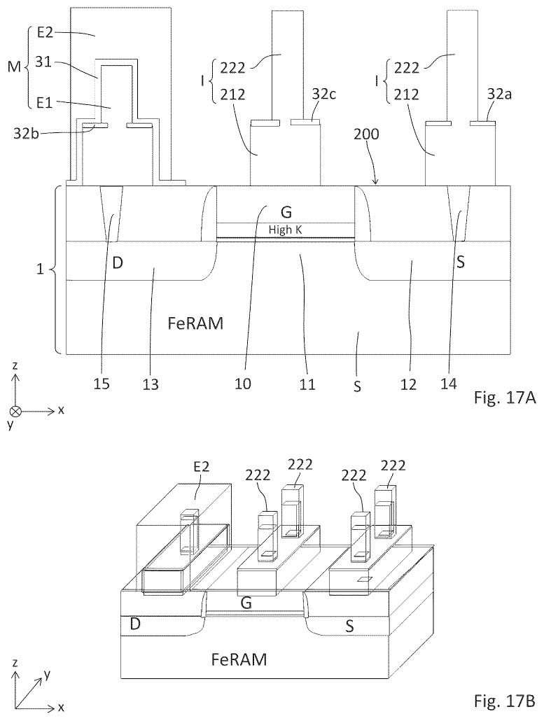

As illustrated in FIGS. 17A, 17B, after removal of the mask 303, a memory element M comprising the first electrode E1, the layer 31 and the second electrode E2 is obtained. This memory element M is connected to the drain 13 of the transistor 1. The memory element M is advantageously integrated in the BEOL interconnecting levels. In this case, it extends along the first, second and third metal levels. Simultaneously, interconnections I (222, 212), connected respectively to the source 12 and to the gate 10 of the transistor 1, are also obtained.

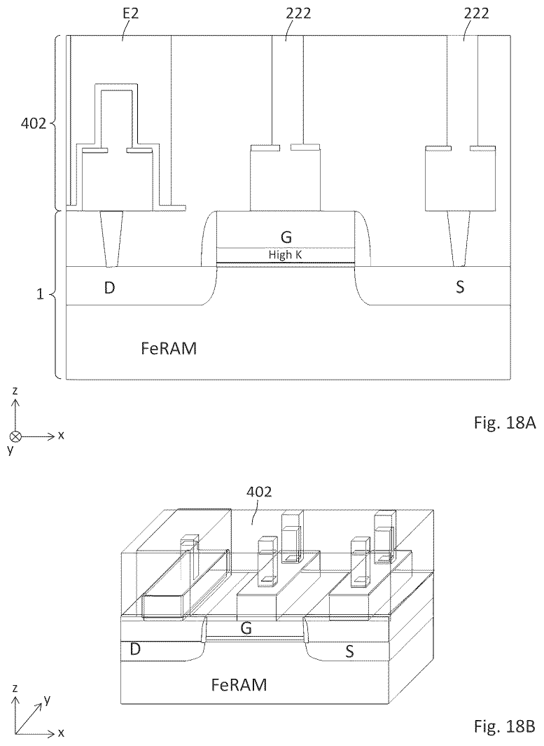

As illustrated in FIGS. 18A, 18B, the interconnections I and the memory element M are then conventionally integrated in a dielectric matrix by deposition and planarisation of a dielectric layer 402, typically SiO₂-based.

A memory cell, for example, of the 1T1R type, comprising a selection transistor 1 and a three-dimensional memory element M integrated in the interconnecting levels, is advantageously produced.

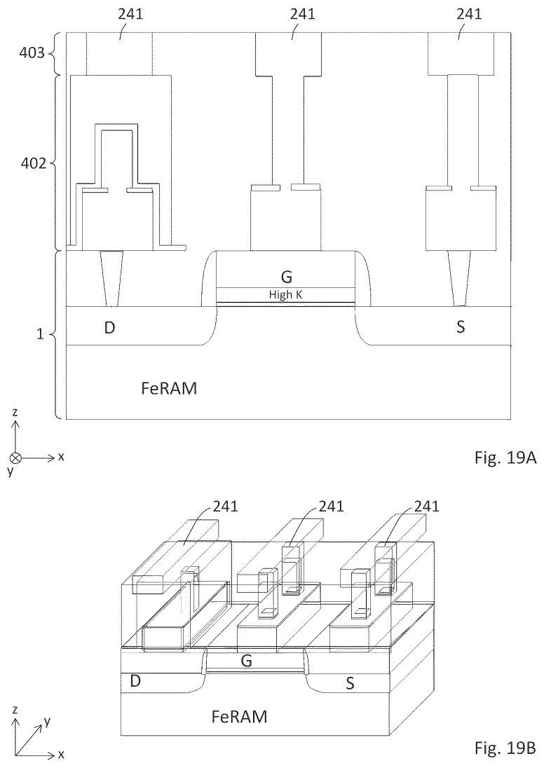

As illustrated in FIGS. 19A, 19B, a fourth metal layer, corresponding, for example, to a fourth metal level, can then be deposited on the layer 402, the electrode E2 and the vias 222 are flush. This fourth metal layer is typically structured in the form of lines 241 connecting the electrode E2 and the vias 222. This fourth metal level can then be integrated in a dielectric matrix by deposition and planarisation of a typically SiO₂-based dielectric layer 403

The invention is not limited to the embodiments described above. In particular, it can be considered to structure the interconnections and the memory element differently. The dimensions of the vias, of the lines and of the electrodes can vary, according to the required performance specifications for the memory cells and/or according to the chosen application.

1. A non-volatile memory device comprising, in a stack along a direction z:
a selection element comprising at least two electrodes,
an interconnection connecting at least one of said two electrodes,
a memory element comprising:
a first electrode connecting the other of said at least two electrodes of the selection element, the first electrode comprising:
a metal line with the basis of a first metal,
a metal via with the basis of a second metal, and
a portion of an etching stop layer inserted between the via and the line, said portion comprising at least one via opening, such that the via and the line are connected through at least one via opening,
a layer with the basis of a dielectric or ferroelectric material covering the line and the via, and
a second electrode surmounting the layer with the basis of the dielectric or ferroelectric material.

2. The device according to claim 1, wherein the layer with the basis of a dielectric or ferroelectric material has at least one horizontal portion, extending perpendicularly to the direction z, separating the first and second electrodes, and at least one vertical portion extending parallel to the direction z, separating the first and second electrodes.

3. The device according to claim 2, wherein the at least one horizontal portion comprises a first horizontal portion on the metal via of the first electrode and a second horizontal portion on the portion of the etching stop layer of the memory element, and wherein the at least one vertical portion comprises a first vertical portion on at least one flank of the metal via of the first electrode and a second vertical portion on at least one flank of the metal line of the first electrode.

4. The device according to claim 1, wherein the metal via of the first electrode of the memory element has a critical dimension CDᵥᵢₐ₂₂₁, taken along an axis x perpendicular to the direction z, greater than or equal to a dimension CDₒₚₑₙ of the at least one via opening taken along the axis x.

5. The device according to claim 1, wherein the layer with the basis of a dielectric or ferroelectric material is with the basis of a ferroelectric material taken from among: HfₓZr₁₋ₓO₂, HfO₂ doped by at least one from among the following doping elements: Si, N, Gd, Y, Sc, and Ge, with a concentration of doping elements of between 0.5% and 10% at.

6. The device according to claim 1, wherein the layer with the basis of a dielectric or ferroelectric material is with the basis of a dielectric material taken from among: HfOₓ, TaOₓ with 1.8≤x≤2.

7. The device according to claim 1, wherein the selection element is taken from among: a field effect transistor or a field effect ferroelectric transistor, a diode, and a selector.

8. The device according to claim 1, comprising, in a stack along a direction z:
a transistor comprising a gate surmounting a channel, a source and a drain on either side of the channel,
an interconnection connecting the source, comprising:
a metal line with the basis of the first metal,
a metal via with the basis of the second metal, connected to said at least one metal line, and
a first portion (32a) of the etching stop layer inserted between the via and the line, said first portion (32a) comprising at least one via opening, such that the via and the line are connected through said at least one via opening,
a memory element connecting the drain, comprising:
a first electrode connected to the drain comprising:
a metal line with the basis of the first metal,
a metal via with the basis of the second metal, and
a second portion of the etching stop layer inserted between the via and the line, said second portion comprising at least one via opening, such that the via and the line are connected through said at least one via opening,
a layer with the basis of a dielectric or ferroelectric material covering the line and the via, and
a second electrode surmounting the layer with the basis of the dielectric or ferroelectric material, and
an interconnexion connecting the gate, comprising:
a metal line with the basis of the first metal,
a metal via with the basis of the second metal, and
a third portion of the etching stop layer inserted between the via and the line, said third portion comprising at least one via opening, such that the via and the line are connected through said at least one via opening.

9. A method for manufacturing a non-volatile memory device according to claim 1, said method comprising:
a provision of a selection element comprising at least two electrodes, each having an exposed face at an upper surface,
a formation of a first metal layer on the exposed faces of the upper surface,
a formation, on the first metal layer, of an etching stop layer,
a structuration of the etching stop layer, through a first mask, so as to expose parts of the first metal layer and to preserve parts of the etching stop layer in the form of a portion surmounting one of said at least two electrodes of the selection element, said portion comprising a via opening, opening onto the first underlying metal layer,
a formation of a second metal layer on the portion of the etching stop layer and on the exposed parts of the first metal layer,
a formation, on the second metal layer, of a second mask defining at least one via in vertical alignment of the via opening of the portion of the etching stop layer, and at least partially, an interconnection in vertical alignment with the other of said at least two electrodes of the selection element,
an etching of the second metal layer, said etching being configured to form, by stopping on the portion of the etching stop layer, a via in vertical alignment with the via opening of said portion and at least partially, the interconnection,
an etching of the first metal layer on either side of the portion of the etching stop layer, said etching being configured to form the interconnection and to form, by stopping on the upper surface, a metal line under said portion, the via and the metal line forming a first electrode of a memory element of the device,
a formation of a layer with the basis of a dielectric or ferroelectric material on the first electrode,
a formation of a third metal layer on the layer with the basis of a dielectric or ferroelectric material,
a formation, on the third metal layer, of a third mask (303) defining at least one via in vertical alignment with the interconnection, and defining a second electrode of the memory element in vertical alignment with the layer with the basis of a dielectric or ferroelectric material, and
an etching of the third metal layer, said etching being configured to form or reform the interconnection, said etching being configured to form, by stopping on the upper surface or on the layer with the basis of a dielectric or ferroelectric material, the second electrode of the memory element.

10. The method according to claim 9, wherein the etching of the second metal layer and the etching of the first metal layer are sequenced along one single and same sequence of etchings.

11. The method according to claim 9, wherein the formation of the layer with the basis of the dielectric or ferroelectric material comprises:
a conform deposition of the layer with the basis of the dielectric or ferroelectric material on the first electrode and on the interconnection, and
a structuration by lithography and etching, so as to remove parts of the layer with the basis of the dielectric or ferroelectric material deposited on the interconnection, and to preserve a part of the layer with the basis of the dielectric or ferroelectric material deposited on the first electrode.

12. The method according to claim 9, further comprising, after formation of the layer with the basis of the dielectric or ferroelectric material, a deposition of a diffusion barrier layer.

13. A method according to claim 9, wherein the etching stop layer is with the basis of a material taken from among: SiO₂, TiO₂, HfO₂, HfN, ZrN, SiN, and SiCN.

14. The method according to claim 9, comprising:
a provision of a transistor comprising a gate surmounting a channel, a source and a drain on either side of the channel, and vias connecting the source and the drain, said vias and said gate, each having an exposed face at an upper surface,
a formation of a first metal layer on the exposed faces of the upper surface,
a formation, on the first metal layer, of an etching stop layer having a selectivity at the etching S_{21:30} greater than or equal to 5:1 with respect to the first metal layer,
a structuration of the etching stop layer, through a first mask (301), so as to expose parts of the first metal layer and to preserve parts of the etching stop layer in the form of first and second portions each surmounting vias connecting the source and the drain, and of a third portion surmounting the gate of the transistor, said first, second and third portions, each comprising a via opening, opening onto the first underlying metal layer,
a formation of a second metal layer on the first, second and third portions of the etching stop layer and on the exposed parts of the first metal layer,
a formation, on the second metal layer, of a second mask defining vias in vertical alignment with the via openings of the first, second and third portions of the etching stop layer,
an etching of the second metal layer, said etching being configured to form, by stopping on the first, second and third portions of the etching stop layer, respectively a first via in vertical alignment with the via opening of the first portion, a second via in vertical alignment with the via opening of the second portion, a third via in vertical alignment with the via opening of the third portion,
an etching of the first metal layer on either side of the first, second and third portions of the etching stop layer, said etching being configured to form, by stopping on the upper surface, a first metal line under the first portion, a second metal line under the second portion, a third metal line under the third portion, the second via and the second metal line forming a first electrode of a memory element of the device,
a formation of a layer with the basis of a dielectric or ferroelectric material on the first electrode,
a formation of a third metal layer on the layer with the basis of a dielectric or ferroelectric material and on the second and third vias,
a formation, on the third metal layer, or a third mask defining vias in vertical alignment of the via openings of the first and third portions of the etching stop layer, and defining a second electrode of the memory element in vertical alignment with the layer with the basis of a dielectric or ferroelectric material, and
an etching of the third metal layer said etching being configured to form or reform, by stopping on the first and third portions of the etching stop layer, respectively the first via in vertical alignment with the via openings of the first portion, the third via in vertical alignment with the via opening of the third portion, said etching being configured to form, by stopping on the upper surface or on the layer with the basis of a dielectric or ferroelectric material, the second electrode of the memory element.
